(19) United States
(12) Patent Application Publication
(10) Pub. No.: US 2007/0051866 A1
(43) Pub. Date: Mar. 8, 2007

(54) Mold and method for manufacturing the same

(75) Inventor: Shih-Chieh Yen, Tu-Cheng (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI Precision Industry CO., LTD., Tu-Cheng City (TW)

(21) Appl. No.: 11/437,452

(22) Filed: May 19, 2006

(30) Foreign Application Priority Data
Sep. 7, 2005 (CN) 200510037115.9

(51) Int. Cl. B28B 7/00; C23C 14/00; B22C 3/00

(52) U.S. Cl. 249/114.1; 427/135; 427/524

(57) ABSTRACT

The present invention discloses a mold and a method for manufacturing the mold. The mold includes a mold matrix having a molding surface, and a protective layer formed on the molding surface. The protective layer is made of a material chosen from the group consisting of iridium-rhenium alloy with a chromium nitride added therein and iridium-ruthenium alloy with a chromium nitride added therein. The method mainly includes the steps of: providing a mold matrix having a molding surface in a vacuum sputtering chamber, the vacuum sputtering chamber comprising a first target, the first target being comprised of a material chosen from the group consisting of iridium-rhenium alloy with a chromium nitride added therein and iridium-ruthenium alloy with a chromium nitride added therein; and forming a protective layer on the molding surface of the mold matrix by sputtering a target.

### TECHNICAL FIELD

The present invention relates to molds such as those used for making transparent elements and, more particularly, to a mold and a method for manufacturing the mold.

### BACKGROUND

Transparent elements, especially aspheric glass lenses, are widely used in digital cameras, video recorders, compact disc players and other optical systems due to their excellent optical properties. At present, a molding process is commonly used for manufacturing of the transparent elements. In the molding process, a mold generally is used for molding the transparent elements.

In general, molds are exposed to repeated impacts and high temperatures during molding. Thus, these molds need characteristics such as excellent hardness, high wear resistance, good oxidation resistance and chemical resistance, easy separability (i.e. easy mold release), mirror surface workability, etc. A variety of suitable materials may be applied for construction of the mold; for example, glasslike or vitreous carbon, silicon carbide, silicon nitride, and a mixture containing silicon carbide. However, the materials may easily adhere to molded products so that the products cannot be released from molds. In addition, the materials may be easily oxidized due to being subjected to high temperatures in air. The mold would be increasingly deteriorated due to frequent oxidization thereby reducing working life thereof.

In order to overcome shortcomings set out above, a protective layer is generally applied on a mold substrate, for example a mold matrix. That is, this mold typically includes a mold matrix and a protective layer formed thereon. The protective layer typically can separate the mold matrix from directly contacting with the products and does not adhere to the product. As such, the product is readily released from the mold. Also, the protective layer can prevent the mold matrix from being oxidized thereby increasing the working life of the mold.

Nowadays, a typical protective layer having above-mentioned abilities is made of an unreactive metal or an alloy thereof, such as, for example, platinum (Pt), palladium (Pd), rhodium (Rh), or alloys thereof Nevertheless, these inert metals have disadvantageous properties, for example, being relatively soft and expensive.

What is needed, therefore, is a mold that is relatively hard and cheap.

What is also needed, therefore, is a method for manufacturing the above-described mold.

### SUMMARY

In accordance with a preferred embodiment, a mold includes a mold matrix having a molding surface configured for forming a contour of a product molded by the mold, and a protective layer formed on the molding surface. The protective layer is made of either iridium-rhenium alloy with a chromium nitride added therein, or iridium-ruthenium alloy with a chromium nitride added therein, or a combination of the two.

A method for manufacturing the mold includes the steps of providing a mold matrix having a molding surface in a vacuum sputtering chamber, the vacuum sputtering chamber comprising a target, the target being comprised of either iridium-rhenium alloy with a chromium nitride added therein, or iridium- ruthenium alloy with a chromium nitride added therein, or a combination of the two; and forming a protective layer on the molding surface of the mold matrix by sputtering the target.

Other advantages and novel features will be drawn from the following detailed description of preferred embodiments when conjunction with the attached drawings, in which:

### BRIEF DESCRIPTION OF THE DRAWINGS

Many aspects of the present mold can be better understood with reference to the following drawings. The components in the drawings are not necessarily drawn to scale, the emphasis instead being placed upon clearly illustrating the principles of the present mold. Moreover, in the drawings, like reference numerals designate corresponding parts throughout the several views.

FIG. 1 is a schematic, cross-sectional view of a mold according to a first preferred embodiment;

FIG. 2 is flow chart of a method for manufacturing the mold of FIG. 1;

FIG. 3 is a schematic, cross-sectional view of another mold according to a second preferred embodiment; and

FIG. 4 is flow chart of a method for manufacturing the mold of FIG. 3.

### DETAILED DESCRIPTION OF THE PREFERRED EMBODIMENTS

Embodiments of the present invention will now be described in detail below and with reference to the drawings.

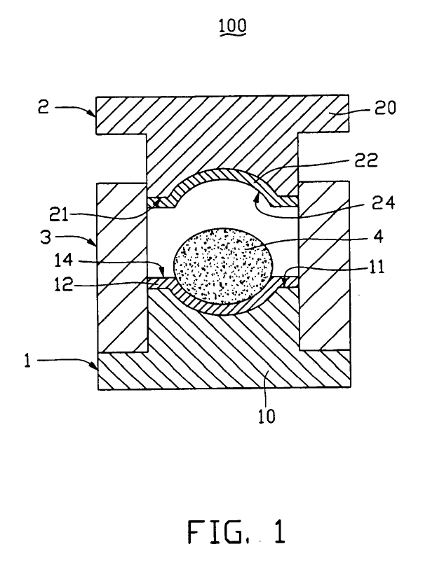

FIG. 1 illustrates a mold 100 in accordance with a first preferred embodiment. The mold 100 is typically in two structure forms, for example, a lower mold 1 and an upper mold 2 . A guide member 3 is generally applied to the mold 100 to guide relative movement of the lower and upper molds 1, 2 along a path defined by the guide member 3, thereby molding a desired product 4 (e.g. an optical glass element) therebetween.

The lower and upper mold 1, 2 include mold matrices 10, 20, and protective layers 12, 22, respectively. The two matrices 10, 20 have opposite molding surfaces 11, 21 respectively. The two molding surfaces 11, 21 cooperatively define a molding form, namely, an external contour of the element 4 to be molded. The protective layers 12, 22 are formed on the molding surfaces 11, 21, respectively The two protective layers 12, 22 have exposed surfaces 14, 24 facing towards each other. The exposed surfaces 14, 24 have corresponding forms essentially similar to their respective molding surfaces 11, 21.

Depending on performance requirements such as heat resistance, hardness, compression resistance, etc., the two mold matrices 10, 20 are generally made of materials of varying hardness. For example, the two mold matrices 10, 20 are advantageously made of a material selected from the group consisting of tungsten carbide, silicon carbide, titanium carbide, silicon nitride, magnesium oxide, zinc oxide, and their combinations.

The two protective layers 12, 22 are advantageously made of either an iridium-rhenium (Ir—Re) alloy with a chromium nitride added therein, or an iridium-ruthenium (Ir—Ru) alloy with a chromium nitride added therein, or a combination of the two. In general, a ratio of Ir to Re and a ratio of Ir to Ru are preferably about 4:1. In this ratio, the two protective layers 12, 22 can steadily adhere to 10, 20 and readily separated from products molded by the mold 100. Due to the presence of the chromium nitride added in the two alloys, the ratios ranges of Ir to Re and Ir to Ru are beneficially widened from about 1:4 to about 4:1 whilst still readily maintaining good separation from the products and firmly adhering to the mold matrices 10, 20.

The chromium nitride are advantageously dichromium nitride (Cr₂N) or chromium mononitride (CrN). The Cr₂N is added into the Ir—Re alloy or Ir—Re alloy, thereby forming a Cr₂N—Ir—Re alloy. The CrN is added into the Ir—Re alloy or Ir—Re alloy, thereby forming a CrN—Ir—Re alloy.

The two protective layers 12, 22 advantageously have a thickness in the approximate range from 5 nanometers to 20 nanometers. The two protective layers 12, 22 could be formed on the molding surfaces 11, 21, for example, by a sputtering method.

The manufacturing method of the mold 100 mainly includes the steps of: providing a mold matrix having a molding surface in a vacuum sputtering chamber, the vacuum sputtering chamber including a target, the target being comprised of a material chosen from the group consisting of iridium-rhenium alloy with a chromium nitride added therein and iridium-ruthenium alloy with a chromium nitride added therein; and forming a protective layer on the molding surface of the mold matrix by sputtering the target.

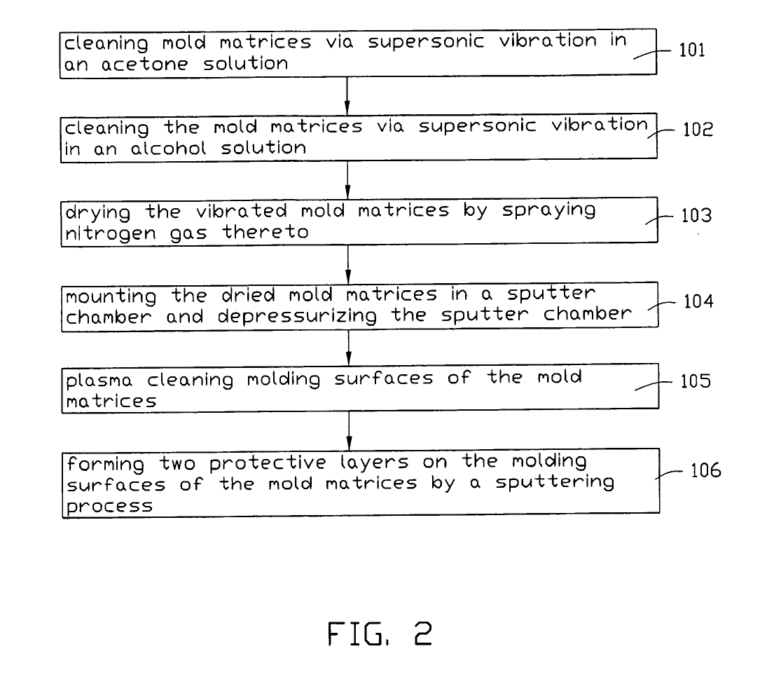

Referring to FIGS. 1 and 2, for manufacturing the mold 100 in two structure forms, in an embodiment, the initial step could advantageously include pretreatment steps to the mold matrices 10, 20. The pretreatment steps mainly include initial cleaning, drying, mounting, secondary cleaning, etc.

The initial cleaning of the mold matrices 10, 20 can be performed, for example, by supersonic vibration of the mold matrices 10, 20 in an organic solution either once or a number of times. The vibration cleaning advantageously takes place for about 10 minutes to about 30 minutes each time. In the illustrated embodiment, in order to achieve effectively cleaning of the mold matrices 10, 20, the initial cleaning beneficially includes two vibration cleaning steps 101 and 102, i.e. cleaning the mold matrices 10, 20 via supersonic vibration in an acetone solution and then cleaning the mold matrices 10, 20 via supersonic vibration in an alcohol solution. The vibration cleaning steps 101 and 102 advantageously take about 20 minutes and about 10 minutes, respectively.

The drying of the initially cleaned mold matrices 10, 20 is performed, for example, by spraying nitrogen gas onto the mold matrices 10, 20, i.e. step 103 as shown in FIG. 2. In the illustrated embodiment, the mounting step, i.e. step 104, advantageously includes mounting of the mold matrices 10, 20 in the sputtering chamber and depressurizing the sputtering chamber. Preferably, the sputtering chamber is advantageously depressurized to a vacuum pressure lower than about 10⁻⁶ torr.

The secondary cleaning is advantageously performed, for example, by plasma cleaning of the molding surfaces 11, 21 of the mold matrices 10, 20. Prior to the plasma cleaning, a certain volume of inert gas is introduced into the sputtering chamber with the mold matrices 10, 20 mounted thereon so as to obtain a pressure of about 2˜7 millitorrs in the sputtering chamber. The plasma cleaning is advantageously performed at a bias voltage from about 100 volts to 300 volts to remove any contaminants from the molding surfaces 11, 21 of the mold matrices 10, 20. The inert gas may be comprised of a gas selected from the group consisting of argon (Ar), helium (He), neon (Ne), xenon (Xe), and nitrogen (N₂).

The second step, in the illustrated embodiment, i.e. step 106, is to form two protective layers 12, 22 on the molding surfaces 11, 21 of the mold matrices 10, 20 by sputtering the target. As such, the protective layers 12, 22 are made of sputtering material in the target, i.e. iridium-rhenium alloy with a chromium nitride added therein and/or iridium-ruthenium alloy with a chromium nitride added therein. In this step, the two protective layers 12, 22 can be separately formed on the respective mold matrices 10, 20 in two sputtering processes. The sputtering bias voltage is advantageously in the approximate range from zero to −50 volts. Thicknesses of the protective layers 12, 22 are advantageously in the approximate range from 5 nanometers to 20 nanometers.

Alternatively, the two protective layers 12, 22 could be synchronously formed on the respective mold matrices 10, 20 in a single sputtering process. In this alternative embodiment, the mold matrices 10, 20 are advantageously mounted in essentially the same location in the sputtering chamber.

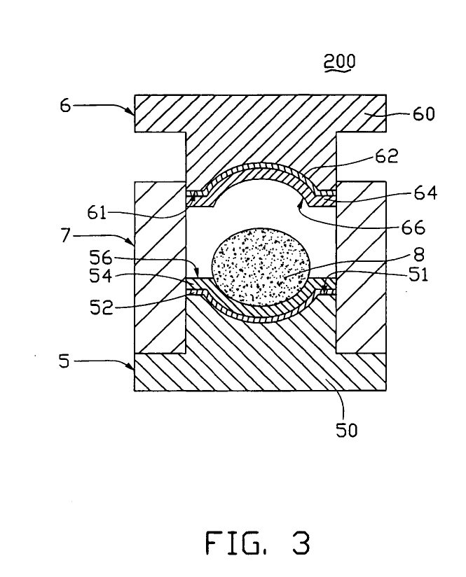

FIG. 3 illustrates another mold 200 in accordance with a second preferred embodiment. The mold 200 is also in two structure forms, for example, a lower mold 6 and an upper mold 5. A guide member 7 is similarly applied to the mold 100 to guide relative movement of the lower and upper molds 5, 6 along a path defined by the guide member 7, thereby molding a desired element 8 (e.g. an optical glass element) therebetween.

The lower and upper molds 5 and 6 include respective mold matrices 50, 60, respective intermediate layers 52, 62, and respective protective layers 54, 64. The two intermediate layers 52, 62 and the two protective layers 54, 64 are formed on top of each other on their respective mold matrices 50, 60 in that order.

The mold matrices 50, 60 are essentially similar to the mold matrices 10, 20 of the mold 100, having similar in structure, shape, material, etc. For example, the two mold matrices 50, 60 have opposite molding surfaces 51, 61 cooperatively defining a molding form, i.e., an external contour of the element 8 to be molded. The protective layers 54, 64 are essentially similar to the protective layers 12, 22 of the mold 100, for example in structure, shape, material, thickness, etc. For example, the protective layers 54, 64 have opposite exposed surfaces 56, 66 having corresponding forms essentially similar to the two molding surfaces 51, 61.

The intermediate layers 52, 62 are formed on their respective molding surfaces 51, 61 of the mold matrix 50, 60, and are disposed between the mold matrices 50, 60 and the protective layers 54, 64, respectively, for strengthening adherence therebetween. The intermediate layers 52, 62 have an advantageous thickness in the approximate range from 50 nanometers to 200 nanometers. The intermediate layers 52, 62 are advantageously made of metal alloy material, for example, Ir—Re alloy, Ir—Re alloy with an additive metal added therein, or Ir—Re alloy with an additive metal added therein. The additive metal could, advantageously, be nickel, iron, cobalt, sliver, tungsten, or chromium.

The manufacturing method of the mold 200 is essentially similar to that of the mold 100, mainly including the steps of: providing a mold matrix having a molding surface in a vacuum sputtering chamber, the vacuum sputtering chamber comprising a first target and a second target; forming an intermediate layer on the molding surface of the mold matrix by sputtering the second target; and forming a protective layer on the intermediate layer by sputtering the first target.

The first target is advantageously comprised of at least one of iridium-rhenium alloy with a chromium nitride added therein and iridium-ruthenium alloy with a chromium nitride added therein. The second target is advantageously comprised of either an iridium-rhenium alloy with an additive metal added therein, or an iridium-ruthenium alloy with an additive metal added therein.

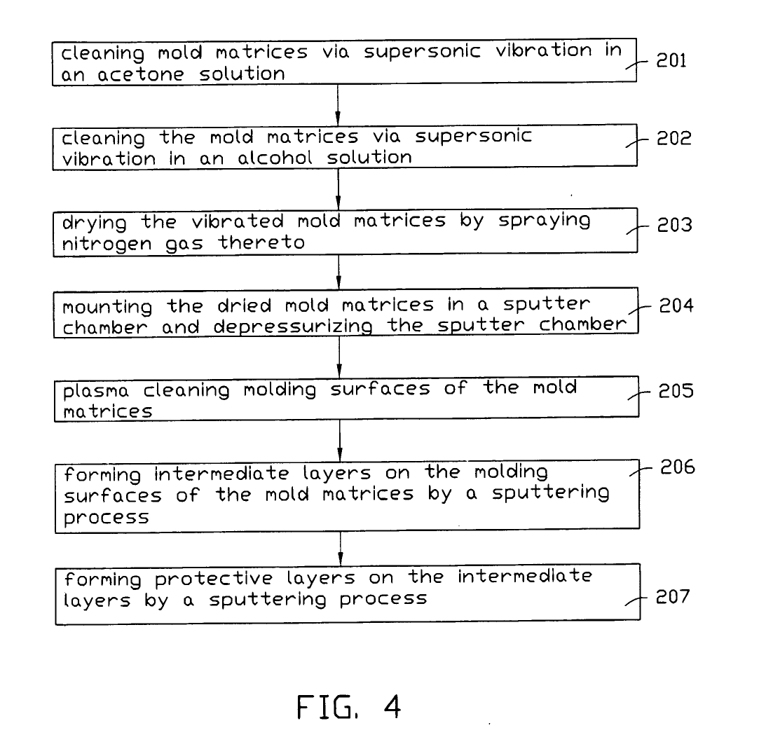

Referring to FIG. 4, the initial step in this method is essentially similar to the initial step in the manufacturing method of the mold 100, including pretreatment steps of initial cleaning, drying, mounting, secondary cleaning, etc. For example, in the illustrated embodiment, the initial step in this method mainly includes: step 201—cleaning the mold matrices 50, 60 via supersonic vibration in an acetone solution; step 202—cleaning the mold matrices 50, 60 via supersonic vibration in an alcohol solution; step 203—drying the vibrated mold matrices 50, 60 by spraying nitrogen gas thereto; step 204—mounting the dried mold matrices 50, 60 in the sputtering chamber and depressurizing the sputtering chamber; and step 205—plasma cleaning the molding surfaces 51, 61 of the mold matrices 50, 60.

The sputtering formations of the intermediate layers 52, 62, i.e., step 206, are advantageously performed at a bias voltage from about zero to about −50 volts by sputtering the second target. As such, the protective layers 12, 22 formed are made of sputtering material in the second target, i.e. iridium-rhenium alloy with an additive metal added therein and/or iridium-ruthenium alloy with an additive metal added therein. Thicknesses of the intermediate layers 52, 62 formed are advantageously in the approximate rage from 50 nanometers to 200 nanometers.

The sputtering formations of the protective layers 54, 64, i.e., step 207, are essentially similar to the sputtering formations of the protective layers 12, 22, i.e., step 106—by sputtering the first target. The sputtering bias voltages are advantageously in the approximate range from zero to −50 volts. Thicknesses of the protective layers 54, 64 formed are advantageously in the approximate range from 5 nanometers to 20 nanometers. Furthermore, the protective layers 54, 64 are formed on the intermediate layers 52, 62, respectively.

In the two molds 100 and 200 above-described, the protective layers 12, 22, 54, 64 are made of either iridium-rhenium with a chromium nitride added therein or iridium-ruthenium alloy with a chromium nitride added therein, or a combination of the two. The chromium nitride is relatively hard thereby increasing mechanical hardness of the iridium-rhenium and iridium-ruthenium alloy, as well as increasing wear resistance thereof. As such, working lives of the two molds 100 and 200 are increased. Furthermore, the chromium nitride is relatively cheap thereby decreasing cost of the two molds 100 and 200.

It will be understood that the above particular embodiments and methods are shown and described by way of illustration only. The principles and features of the present invention may be employed in various and numerous embodiments thereof without departing from the scope of the invention as claimed. The above-described embodiments illustrate the scope of the invention but do not restrict the scope of the invention.

What is claimed is:

1. A mold comprising:
a mold matrix having a molding surface configured for forming a contour of a product molded by the mold; and
a protective layer formed on the molding surface, the protective layer being made of a material chosen fiom the group consisting of iridium-rhenium alloy with a chromium nitride added therein and iridium-ruthenium alloy with a chromium nitride added therein.

2. The mold as claimed in claim 1, further comprising an intermediate layer formed between the mold matrix and the protective layer.

3. The mold as claimed in claim 2, wherein the intermediate layer is made of a material chosen from the group consisting of iridium-rhenium alloy with an additive metal added therein and iridium-ruthenium alloy with an additive metal added therein.

4. The mold as claimed in claim 3, wherein the additive metal is comprised of a material selected from the group consisting of: nickel, iron, cobalt, sliver, tungsten, and chromium.

5. The mold as claimed in claim 2, wherein the intermediate layer has a thickness in the approximate range from 50 nanometers to 200 nanometers.

6. The mold as claimed in claim 1, wherein the chromium nitride is at least one of dichromium nitride and chromium mononitride.

7. The mold as claimed in claim 1, wherein the mold matrix is made of a material selected fiom the group consisting of: tungsten carbide, silicon carbide, titanium carbide, silicon nitride, magnesium oxide, zinc oxide, and their combinations.

8. The mold as claimed in claim 1, wherein ratios of both iridium to rhenium and iridium to ruthenium in respective iridium-rhenium and iridium-ruthenium alloys are in the approximate range from 1:4 to 4:1 by weight.

9. The mold as claimed in claim 1, wherein the protective layer has a thickness in the approximate range from 5 nanometers to 20 nanometers.

10. A method for manufacturing a mold, comprising the steps of:
providing a mold matrix having a molding surface in a vacuum sputtering chamber, the vacuum sputtering chamber comprising a target, the target being comprised of a material chosen from the group consisting of iridium-rhenium alloy with a chromium nitride added therein and iridium-ruthenium alloy with a chromium nitride added therein;
forming a protective layer on the molding surface of the mold matrix by sputtering the target.

11. The method as claimed in claim 10, further comprising pretreatment steps of initially cleaning the mold matrix in an organic solution.

12. The method as claimed in claim 11, further comprising a sequential pretreatment step of drying the cleaned mold matrix.

13. The method as claimed in claim 12, further comprising another sequential pretreatment step of a secondary cleaning of the molding surface of the dried mold matrix.

14. The method as claimed in claim 10, further comprising a step of forming an intermediate layer on the molding surface of the mold matrix by sputtering another target disposed in the sputtering chamber prior to the formation of the protective layer, the another target being comprised of a material chosen from the group consisting of iridium-rhenium alloy with an additive metal added therein and iridium-ruthenium alloy with an additive metal added therein.

15. The method as claimed in claim 14, wherein the intermediate layer formed has a thickness in the approximate range from 50 nanometers to 200 nanometers.

16. The method as claimed in claim 10, wherein a bias voltage from zero to −50 volts is applied for sputtering and forming the protective layer.

17. The method as claimed in claim 10, wherein ratios of both iridium to rhenium and iridium to ruthenium in respective iridium-rhenium and iridium-ruthenium alloy are in the approximate range from 1:4 to 4:1 by weight.

18. The method as claimed in claim 10, wherein the protective layer formed has a thickness in the approximate range from 5 nanometers to 20 nanometers.
